(19) United States
(12) Patent Application Publication
(10) Pub. No.: US 2009/0001422 A1
(43) Pub. Date: Jan. 1, 2009

(54) SEMICONDUCTOR APPARATUS AND MANUFACTURING METHOD THEREOF

(75) Inventors: Junichi OKAYASU, Tokyo (JP); Takuya OIZUMI, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, Tokyo (JP)

(21) Appl. No.: 11/874,927

(22) Filed: Oct. 19, 2007

(30) Foreign Application Priority Data
Dec. 14, 2006 (JP) 2006-337387

(51) Int. Cl. H01L 21/337; H01L 29/80; H01L 21/203; H01L 29/205

(52) U.S. Cl. 257/192; 438/191; 438/483; 257/615; 257/E21.448; 257/E29.315; 257/E21.097; 257/E29.091

(57) ABSTRACT

There is provided a manufacturing method of a semiconductor apparatus, including forming an InGaP layer on a substrate, forming a gate electrode having a Ti layer and an Au layer by vapor deposition on an upper surface of the InGaP layer, further forming a GaAs layer on the upper surface of the InGaP layer in a region different from a region in which the gate electrode is formed, and further forming a source electrode and a drain electrode on an upper surface of the GaAs layer. When the gate electrode having the Ti and Au layers is formed on the upper surface of the InGaP layer, the Ti and Au layers are formed with a substrate temperature being set equal to or lower than 180° C.

### CROSS REFERENCE TO RELATED APPLICATION

The present application claims priority from a Japanese Patent Application(s)

No. 2006-337387 filed on Dec. 14, 2006, the contents of which are incorporated herein by reference.

### BACKGROUND

1. Technical Field

The present invention relates to a semiconductor apparatus and a manufacturing method of the same. More particularly, the present invention relates to a semiconductor apparatus, such as a high electron mobility transistor, in which an electrode is formed on an InGaP layer, and a manufacturing method of the same.

2. Related Art

High electron mobility transistors (HEMTs) are known as one type of field effect transistors which are formed by using a compound semiconductor. The HEMT is a field effect transistor which is formed by depositing semiconductors having different bandgaps, and functions based on such a principle that electrons (a two-dimensional electron gas) are generated at the boundary between the two semiconductors and move at a high speed. For example, there is a known HEMT formed by an electron supply layer made of InGaP (indium-gallium-phosphor) and a channel layer made of InGaAs (indium-gallium-arsenic (See Patent Documents 1, 2 and 3, for example).

[Patent Document 1] Unexamined Japanese Patent Application Publication No. 1998-228763

[Patent Document 2] Unexamined Japanese Patent Application Publication No. 1989-238175

[Patent Document 3] Unexamined Japanese Patent Application Publication No. 1991-44038

The HEMT has a gate electrode provided on the electron supply layer. Here, the crystal structure of the electron supply layer at the junction boundary with the gate electrode significantly affects the mobility of the two-dimensional electron gas in the HEMT. To be specific, if the electron supply layer has a small number of crystal faults at the junction boundary with the gate electrode, the trap states are reduced. Therefore, the HEMT operates at a high speed, thereby achieving fast transient responses for fast signals such as pulses which are input into the gate. Such faster transient responses are generally referred to as the gate-lag phenomenon, which shortens the gate-lag and settling time.

In the HEMT having the electron supply layer made of InGaP, the gate electrode is formed on the InGaP layer and is made of, for example, Ti×Mo×Au which partially includes a high melting point material (e.g. Mo) with a melting point of 1700° C. or higher. In order to deposit such a high melting point material by using electron beam evaporation, however, the electron beam to be irradiated requires a high energy. Here, if the electron beam evaporation is conducted with the use of an electron beam having a high energy, the particles of the high melting point material collide with the surface of the InGaP layer at a high speed. This collision enormously damages the crystal structure of the surface of the InGaP layer. For the above-described reasons, if the electron supply layer is made of InGaP and the gate electrode is formed by depositing a high melting point material by using electron beam evaporation, the HEMT may not operate at a high speed and thus suffer from long gate-lag and settling time.

Also, the HEMT may have a silicon nitride film disposed on the surfaces of the electron supply layer and gate electrode to protect the electron supply layer and gate electrode. Here, the silicon nitride film is formed by using the plasma chemical vapor deposition (CVD) method.

In order to form the silicon nitride film by using the plasma CVD method, the substrate temperature is generally raised to 250° C. or higher. Here, if the silicon nitride film is formed in the HEMT having the electron supply layer made of InGaP, the application of heat to the substrate oxidizes InGaP, so that P is removed. This removal also significantly damages the crystal structure of the surface of the InGaP layer. For the above-described reasons, if the electron supply layer is made of InGaP and the silicon nitride film is formed on the InGaP layer, the HEMT may not operate at a high speed and suffer from long gate-lag and settling time.

### SUMMARY

Therefore, it is an object of an aspect of the present invention to provide a manufacturing method of a semiconductor apparatus which is capable of overcoming the above drawbacks accompanying the related art, and a semiconductor apparatus. The above and other objects can be achieved by combinations described in the independent claims. The dependent claims define further advantageous and exemplary combinations of the present invention.

According to an aspect related to the innovations herein, one exemplary manufacturing method may include a manufacturing method of a semiconductor apparatus. The manufacturing method includes forming an InGaP layer on a substrate, and forming a gate electrode by vapor deposition on an upper surface of the InGaP layer. Here, the gate electrode has a Ti layer and an Au layer.

According to an aspect related to the innovations herein, one exemplary semiconductor apparatus may include a semiconductor apparatus manufactured by forming an InGaP layer on a substrate, and forming a gate electrode by vapor deposition on an upper surface of the InGaP layer. Here, the gate electrode has a Ti layer and an Au layer.

According to an aspect related to the innovations herein, one exemplary manufacturing method may include a manufacturing method of a semiconductor apparatus. The manufacturing method includes forming an InGaP layer on a substrate, forming an electrode on an upper surface of the InGaP layer, producing SiN, and depositing the SiN on the upper surface of the InGaP layer so as to form an insulating layer.

According to an aspect related to the innovations herein, one exemplary semiconductor apparatus may include a semiconductor apparatus manufactured by forming an InGaP layer on a substrate, forming an electrode on an upper surface of the InGaP layer, producing SiN, and depositing the SiN on the upper surface of the InGaP layer so as to form an insulating layer.

According to an aspect related to the innovations herein, one exemplary manufacturing method may include a manufacturing method of a semiconductor apparatus. The manufacturing method includes forming an InGaP layer on a substrate, forming a GaAs layer on an upper surface of the InGaP layer, removing a portion of the GaAs layer which corresponds to a gate formation region by using wet etching, and forming a gate electrode on a portion of the upper surface of the InGaP layer which becomes exposed by the removal of the portion of the GaAs layer.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates the cross-sectional structure of a high electron mobility transistor 10 relating to an embodiment of the present invention.

FIG. 2 illustrates the manufacturing process of the high electron mobility transistor 10 shown in FIG. 1, and shows the cross-sectional structure of the high electron mobility transistor 10 in which a GaAs layer 26 has been formed.

FIG. 3 illustrates the manufacturing process of the high electron mobility transistor 10 shown in FIG. 1, and shows the cross-sectional structure of the high electron mobility transistor 10 in which a hollow portion 48 has been formed.

FIG. 4 illustrates the manufacturing process of the high electron mobility transistor 10 shown in FIG. 1, and shows the cross-sectional structure of the high electron mobility transistor 10 in which a recess 50 has been formed.

FIG. 5 illustrates the manufacturing process of the high electron mobility transistor 10 shown in FIG. 1, and shows the cross-sectional structure of the high electron mobility transistor 10 in which a gate electrode 20 has been formed.

FIG. 6 illustrates the manufacturing process of the high electron mobility transistor 10 shown in FIG. 1, and shows the cross-sectional structure of the high electron mobility transistor 10 in which an SiN layer 30 has been formed.

FIG. 7 illustrates the cross-sectional structure of a modification example of the high electron mobility transistor 10 relating to the embodiment.

FIG. 8 illustrates the manufacturing process of the high electron mobility transistor 10 shown in FIG. 7, and shows the cross-sectional structure of the high electron mobility transistor 10 in which the hollow portion 48 has been formed.

FIG. 9 illustrates the manufacturing process of the high electron mobility transistor 10 shown in FIG. 7, and shows the cross-sectional structure of the high electron mobility transistor 10 in which the recess 50 has been formed.

FIG. 10 illustrates the manufacturing process of the high electron mobility transistor 10 shown in FIG. 7, and shows the cross-sectional structure of the high electron mobility transistor 10 in which the gate electrode 20 has been formed.

FIG. 11 illustrates the manufacturing process of the high electron mobility transistor 10 shown in FIG. 7, and shows the cross-sectional structure of the high electron mobility transistor 10 in which the SiN layer 30 has been formed.

FIG. 12 illustrates the settling characteristics of the high electron mobility transistor 10 relating to the embodiment of the present invention and the settling characteristics of a high electron mobility transistor relating to a comparative example.

FIG. 13 illustrates the characteristics shown in FIG. 12 in smaller units in terms of the horizontal axis (time axis).

### DESCRIPTION OF EXEMPLARY EMBODIMENTS

Hereinafter, an aspect of the present invention will be described through an embodiment. The embodiment does not limit the invention according to the claims, and all the combinations of the features described in the embodiment are not necessarily essential to means provided by aspects of the invention.

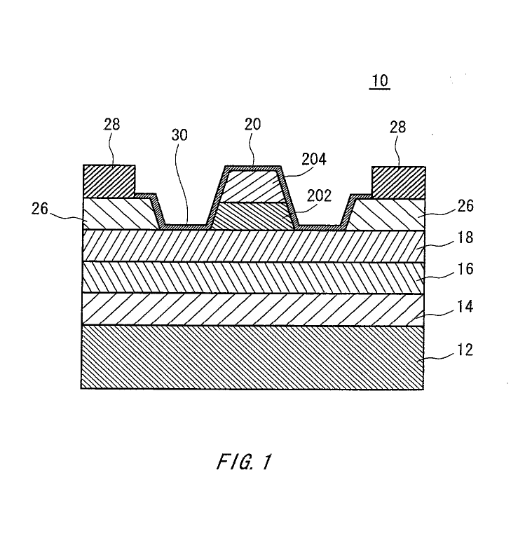

FIG. 1 illustrates the cross-sectional structure of a high electron mobility transistor 10 relating to an embodiment of the present invention. The high electron mobility transistor 10 is shown as an example of a semiconductor apparatus relating to the present invention.

The high electron mobility transistor 10 includes therein a GaAs semiconductor substrate 12, an AlGaAs layer 14, an InGaAs layer 16, an InGaP layer 18, a gate electrode 20, a GaAs layer 26, source/drain electrodes 28, and an SiN layer 30. The GaAs semiconductor substrate 12 has a shape of a flat plate. The AlGaAs layer 14 is formed as a thin film on the GaAs semiconductor substrate 12. The AlGaAs layer 14 functions as a buffer layer in the high electron mobility transistor 10.

The InGaAs layer 16 is formed as a thin film on the AlGaAs layer 14. The InGaAs layer 16 functions as the channel layer including therein a two-dimensional electron gas in the high electron mobility transistor 10. The InGaP layer 18 is formed as a thin film on the InGaAs layer 16. The InGaP layer 18 functions as the electron supply layer in the high electron mobility transistor 10.

The gate electrode 20 is formed on the upper surface of the InGaP layer 18. The gate electrode 20 has a Ti layer 202 formed on the InGaP layer 18 and an Au layer 204 formed on the Ti layer 202. The Ti layer 202 is formed in such a manner that Ti is deposited by using the electron beam evaporation in a predetermined planar region (a gate formation region) on the InGaP layer 18. The Au layer 204 is formed in such a manner that Au is deposited by using resistance heating evaporation or electron beam evaporation in the gate formation region after the Ti layer 202 has been formed. Here, a gate voltage is applied to the gate electrode 20 during the operation of the high electron mobility transistor 10.

The GaAs layer 26 is formed on a planar region of the InGaP layer 18 which is different from the gate formation region in which the gate electrode is formed. To be more specific, the GaAs layer 26 is formed on the InGaP layer 18 so as to form two different portions opposing each other with the gate electrode 20 sandwiched therebetween. One of the two portions of the GaAs layer 26 functions as a layer to form a contact with the source electrode, and the other functions as a layer to form a contact with the drain electrode.

The source/drain electrodes 28 are respectively formed on the two portions of the GaAs layer 26. The source/drain electrodes 28 form an ohmic contact with the GaAs layer 26. A source voltage and a drain voltage are applied to the source/drain electrodes 28 during the operation of the high electron mobility transistor 10.

The SiN layer 30 is formed as a thin film on, at least, an externally exposed portion of the upper surface of the InGaP layer 18 (i.e. a portion of the upper surface of the InGaP layer 18 on which neither the gate electrode 20 nor the GaAs layer 26 is formed) and the upper and side surfaces of the gate electrode 20. The SiN layer 30 functions as a passivation layer and an insulating layer so as to protect the lower layers including the InGaP layer 18.

Here, the SiN layer 30 has a refractive index of no less than 1.5 and less than 1.9, for example. The SiN layer 30 is formed, for example, in such a manner that SiN is deposited by using the plasma CVD method with the substrate temperature being set at a temperature, for example, within a range from no less than 100° C. to no more than 200° C. (for example, 150° C.).

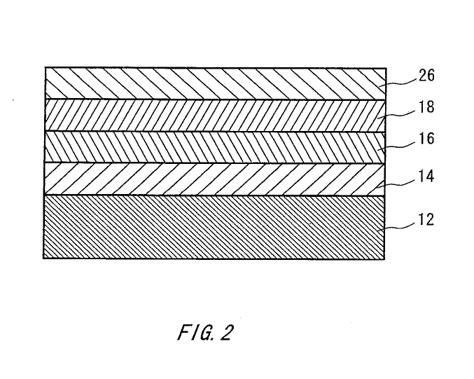

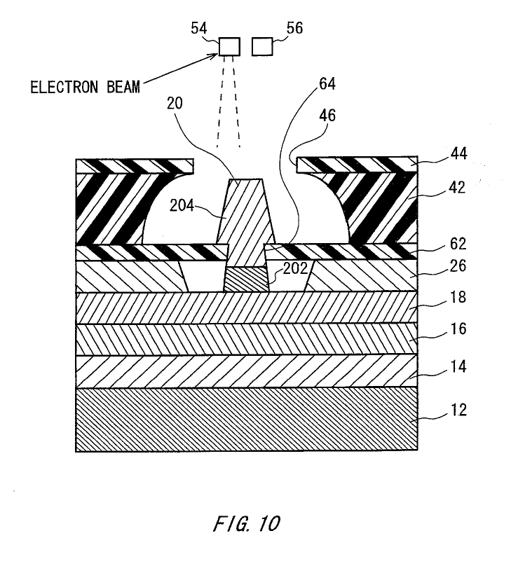

FIGS. 2 to 6 each illustrate the cross-sectional structure which is observed during the manufacturing process of the high electron mobility transistor 10 shown in FIG. 10. The following describes the manufacturing method of the high electron mobility transistor 10 shown in FIG. 1 with reference to FIGS. 2 to 6.

FIG. 2 illustrates the manufacturing process of the high electron mobility transistor 10 shown in FIG. 1 and shows the cross-sectional structure of the high electron mobility transistor 10 in which the GaAs layer 26 has been formed. To manufacture the high electron mobility transistor 10, the AlGaAs layer 14, InGaAs layer 16, InGaP layer 18 and GaAs layer 26 are sequentially deposited on the GaAs semiconductor substrate 12. For example, the AlGaAs layer 14, InGaAs layer 16, InGaP layer 18 and GaAs layer 26 may be formed based on epitaxial growth with the use of the metal organic CVD (MOCVD) method. In this case, the AlGaAs layer 14 may have a film thickness of, for example, 100 nm. The InGaAs layer 16 may have a film thickness of, for example, 10 nm. The InGaP layer 18 may have a film thickness of, for example, 50 nm. The GaAs layer 26 may have a film thickness of, for example, 100 nm.

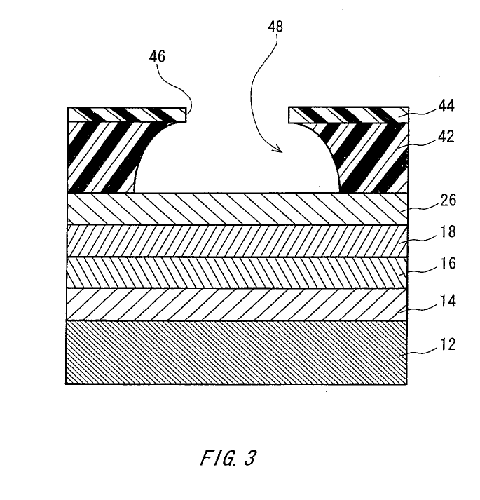

FIG. 3 illustrates the manufacturing process of the high electron mobility transistor 10 shown in FIG. 1, and shows the cross-sectional structure of the high electron mobility transistor 10 in which a hollow portion 48 has been formed. On the GaAs layer 26, a first resist 42 and a second resist 44 are sequentially deposited. Subsequently, portions of the first resist 42 and second resist 44 which correspond to the gate formation region are removed, so that a first opening 46 and the hollow portion 48 are formed. It should be noted here that the first resist 42 has a different sensitivity to light from the second resist 44. For this reason, when the first resist 42 is developed, the partial removal of the first resist 42 expands in the horizontal direction. Therefore, the lower opening of the hollow portion 48 (i.e. where the upper surface of the GaAs layer 26 is externally exposed) is larger than the first opening 46 of the second resist 44.

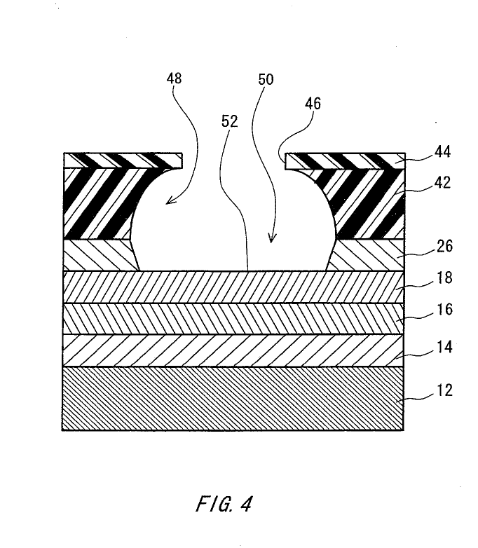

FIG. 4 illustrates the manufacturing process of the high electron mobility transistor 10 shown in FIG. 1, and shows the cross-sectional structure of the high electron mobility transistor 10 in which a recess 50 has been formed. An exposed portion of the GaAs layer 26 is removed by wet etching. This removal forms the recess 50 which has a shape of a dent in the gate formation region on the upper surface of the substrate of the high electron mobility transistor 10.

Here, the crystal structure of the bottom 52 of the recess 50 (i.e. a portion of the upper surface of the InGaP layer 18 which becomes externally exposed by the removal of a portion of the GaAs layer 26) significantly affects the high-frequency characteristics of the high electron mobility transistor 10 (for example, the gate-lag and settling characteristics). According to the present embodiment, the recess 50 is formed by removing a portion of the GaAs layer 26 by using the wet etching technique, in place of dry etching which enormously damages the crystal structure. Therefore, the crystal faults of the InGaP layer 18 can be reduced. As a result, the high electron mobility transistor 10 relating to the present embodiment can achieve excellent high-frequency characteristics (for example, favorable gate-lag and settling characteristics).

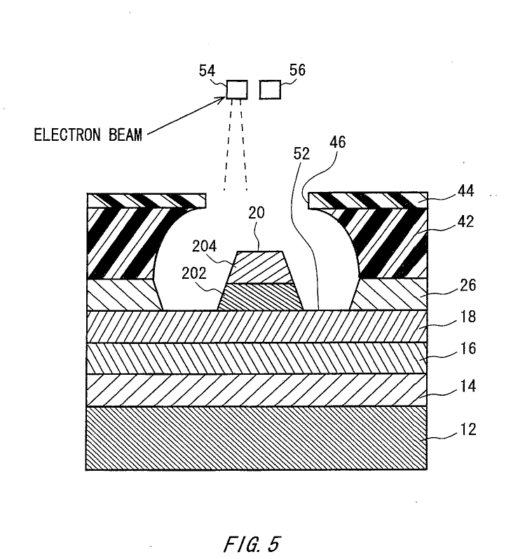

FIG. 5 illustrates the manufacturing process of the high electron mobility transistor 10 shown in FIG. 1, and shows the cross-sectional structure of the high electron mobility transistor 10 in which the gate electrode 20 has been formed. Note that the high electron mobility transistor 10 shown in FIG. 5 is arranged in practice within a suitable apparatus in such a manner that the GaAs semiconductor substrate 12 is positioned higher and a Ti target 54 and an Au metal 56 are positioned lower.

An electron beam is irradiated to the Ti target 54 so as to evaporate the Ti target 54. In this manner, the Ti layer 202 is formed by vapor-deposition on the bottom 52 of the recess 50. After the Ti layer 202 is formed, the Au metal 56 is evaporated by means of resistance heating (or electron beam irradiation), so that the Au layer 204 is formed on the Ti layer 202 by vapor-deposition.

As a result of the above processes, the gate electrode 20 including the Ti layer 202 and Au layer 204 can be formed on the InGaP layer 18. In other words, the gate electrode 20 including the Ti layer 202 and Au layer 204 can be formed by vapor-deposition on the upper surface of the InGaP layer 18. Here, the Ti particles and Au particles produced as a result of the evaporation of the Ti target 54 and Au metal 56 pass through the first opening 46 formed in the second resist 44, to be vapor-deposited on the InGaP layer 18. Here, the Ti and Au particles deposit in the upward direction with respect to the substrate. Therefore, the gate electrode 20 is formed on the InGaP layer 18 at a position corresponding to the first opening 46.

According to the present embodiment, the gate electrode is formed by using Ti and Au which have a lower melting point than molybdenum. This makes it possible to reduce the energy required to perform the vapor-deposition. Which is to say, the Ti and Au particles collide with the InGaP layer 18 at a lower speed. This can reduce the damage caused in the crystal structure of the surface of the InGaP layer 18.

Also, when Ti and Au are vapor-deposited on the upper surface of the InGaP layer, the substrate temperature of the InGaP layer 18 is set to be equal to or lower than 180° C. according to the present embodiment. Therefore, the increase in the temperature of the InGaP layer 18 can be reduced and the stress can be thus decreased, when compared with the case where molybdenum is alternatively used. As a result, the oxidization of the InGaP layer 18 can be reduced during the formation of the gate electrode 20, so as to decrease the removal of P from the crystal structure of the InGaP layer 18.

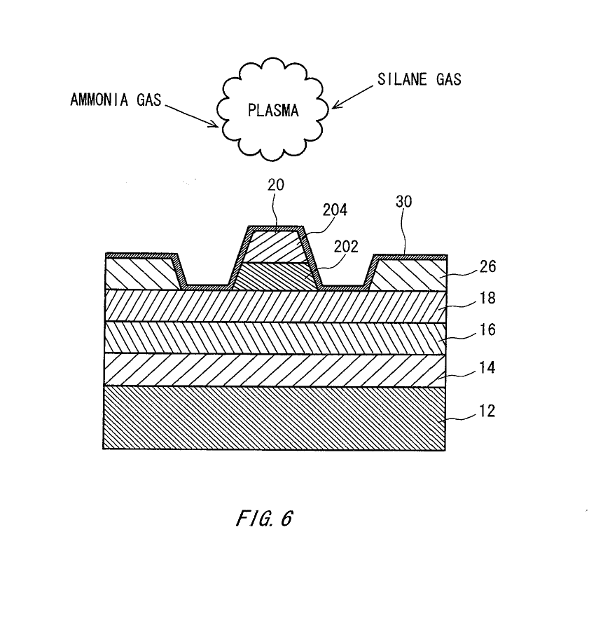

FIG. 6 illustrates the manufacturing process of the high electron mobility transistor 10 shown in FIG. 1, and shows the cross-sectional structure of the high electron mobility transistor 10 in which the SiN layer 30 has been formed. The first and second resists 42 and 44 are removed. Subsequently, SiN having a refractive index of no less than 1.5 and less than 1.9 is deposited on the externally exposed portion of the upper surface of the InGaP layer 18 (that is to say, a portion of the upper surface of the InGaP layer 18 in which neither the gate electrode 20 nor InGaP layer 18 is formed) and the upper and side surfaces of the gate electrode 20. In this way, the SiN layer 30 is formed. For example, SiN may be deposited to form the SiN layer 30 using the plasma CVD method with the substrate temperature being set in a range from no less than 100° C. to no more than 200° C. (for example, 150° C.). Here, SiN may be generated by producing plasmas within an atmosphere of an ammonia gas and a silane gas, for example.

The SiN layer 30 formed in the above-described manner can function as an insulating layer having an oxygen composition ratio of 0.5% or higher. The SiN layer 30 formed in the above-described manner can also function as an insulating layer having a smaller linear thermal expansion coefficient than a film having an SiN composition ratio of substantially 100%.

Generally speaking, when SiN is deposited on a substrate by using the plasma CVD method, the substrate temperature is set so as to fall within a range from no less than approximately 250° C. to no more than approximately 350° C. to generate SiN having a refractive index of no less than 1.90. According to the present embodiment, the substrate temperature is set so as to fall within a range from no less than 100° C. to no more than 200° C. (for example, 150° C.), and SiN having a refractive index of no less than 1.5 and less than 1.9 is deposited. In this way, the present embodiment can reduce the increase in the temperature of the InGaP layer 18 during the formation process of the SiN layer 30. As a result, the present embodiment can reduce the oxidization of the InGaP layer 18 during the formation process of the SiN layer 30, thereby decreasing the removal of P from the crystal structure of the InGaP layer 18.

After this, a portion of the SiN layer 30 which is formed on the GaAs layer 26 is removed, so that the upper surface of the GaAs layer 26 becomes externally exposed. On the upper surface of the GaAs layer 26 which becomes exposed as a result of the partial removal of the SiN layer 30, a metal material which forms an ohmic contact with the GaAs layer 26 is deposited, so that the source/drain electrodes 28 are formed.

By performing the above-described steps, the high electron mobility transistor 10 shown in FIG. 1 can be manufactured. Referring to the high electron mobility transistor 10 manufactured in the above-described manner, the gate electrode 20 is made of Ti and Au which have a low melting point, and the InGaP layer 18 is less damaged during the manufacturing process since the substrate temperature is set low during the deposition of the SiN layer 30. Therefore, the high electron mobility transistor 10 can have fewer crystal faults in the InGaP layer 18. As a result, the high electron mobility transistor 10 can operate at a high speed, and achieve shorter gate-lag and settling time.

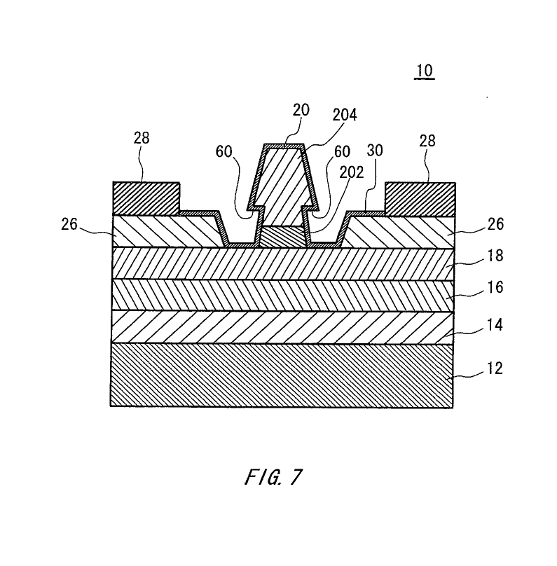

FIG. 7 illustrates the cross-sectional structure of a modification example of the high electron mobility transistor 10 relating to the present embodiment. The constituents of the high electron mobility transistor 10 relating to the present modification example have substantially the same configurations and functions as the corresponding constituents shown in FIG. 1 which are assigned with the same reference numerals, except for some differences. Also, the high electron mobility transistor 10 relating to the present modification example is manufactured in substantially the same manner as the high electron mobility transistor 10 shown in FIG. 1. Therefore, the following explanation is made with a focus on the differences.

According to the present modification example, the gate electrode 20 has, in substantially the middle thereof in the vertical direction, a step portion 60. The portion of the gate electrode 20 higher than the step portion 60 has a larger width than the portion of the gate electrode 20 lower than the step portion 60. Which is to say, the gate electrode 20 has a so-called T-shaped gate structure. Having such a T-shaped gate electrode 20, the high electron mobility transistor 10 can have a small resistance value.

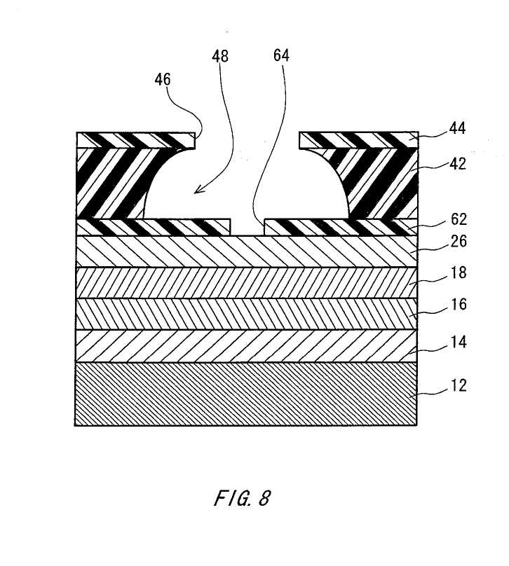

FIGS. 8 to 11 each illustrate the cross-sectional structure of the high electron mobility transistor 10 shown in FIG. 7 which is observed during the manufacturing process. The following describes the manufacturing method of the high electron mobility transistor 10 shown in FIG. 7 with reference to FIGS. 8 to 11.

FIG. 8 illustrates the manufacturing process of the high electron mobility transistor 10 shown in FIG. 7, and shows the cross-sectional structure of the high electron mobility transistor 10 in which the hollow portion 48 has been formed. To manufacture the high electron mobility transistor 10 relating to the present modification example, the AlGaAs layer 14, InGaAs layer 16, InGaP layer 18 and GaAs layer 26 are sequentially deposited on the GaAs semiconductor substrate 12. After this, a third resist 62, the first resist 42, and the second resist 44 are sequentially deposited on the GaAs Layer 26.

Subsequently, the first opening 46 is formed, and the hollow portion 48 is then formed. Following this, a portion of the third resist 62 which corresponds to the gate formation region is removed, to form a second opening 64. Here, the center of the second opening 64 substantially coincides with the center of the first opening 46. Also, the second opening 64 is smaller than the first opening 46 formed in the second resist 44. The internal diameter of the second opening 64 substantially matches the external shape of a portion of the gate electrode 20 which is positioned immediately lower than the step portion 60.

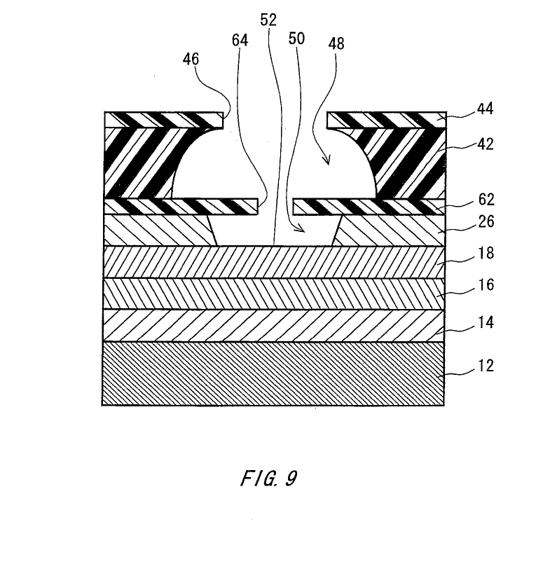

FIG. 9 illustrates the manufacturing process of the high electron mobility transistor 10 shown in FIG. 7, and shows the cross-sectional structure of the high electron mobility transistor 10 in which the recess 50 has been formed. A portion of the GaAs layer 26 which becomes externally exposed by the formation of the second opening 64 is removed by means of wet etching. This removal forms the recess 50 in the gate formation region on the upper surface of the substrate of the high electron mobility transistor 10. Here, the etching process is controlled so as to expand in the horizontal direction. In this way, the recess 50 is formed in such a manner that the bottom 52 thereof (that is to say, the externally exposed portion of the InGaP layer 18) is sufficiently larger than the second opening 64.

FIG. 10 illustrates the manufacturing process of the high electron mobility transistor 10 shown in FIG. 7, and shows the cross-sectional structure of the high electron mobility transistor 10 in which the gate electrode 20 has been formed. Note that the high electron mobility transistor 10 shown in FIG. 10 is arranged in practice within a suitable apparatus in such a manner that the GaAs semiconductor substrate 12 is positioned higher and the Ti target 54 and Au metal 56 are positioned lower.

Subsequently, an electron beam is irradiated to the Ti target 54 so as to evaporate the Ti target 54. In this manner, the Ti layer 202 is formed by vapor-deposition on the bottom 52 of the recess 50. After the Ti layer 202 is formed, the Au metal 56 is evaporated by means of resistance heating (or electron beam irradiation), so that the Au layer 204 is formed on the Ti layer 202 by vapor-deposition. As a result of the above processes, the gate electrode 20 including the Ti layer 202 and Au layer 204 can be formed on the InGaP layer 18.

Here, the Ti particles produced as a result of the evaporation of the Ti target 54 pass through the first opening 46 and second opening 64, to be vapor-deposited on the InGaP layer 18. Here, the Ti particles deposit in the upward direction with respect to the substrate. On the other hand, the Au particles produced as a result of the evaporation of the Au metal 56 pass through the first and second openings 46 and 64, to be vapor-deposited on the Ti layer 202. Here, the Au particles deposit in the upward direction with respect to the substrate. Even after the Au particles deposit up to the third resist 62, the Au particles keep depositing in the upward direction with respect to the substrate. Here, the Au particles are vapor-deposited in the upward direction with respect to the substrate, on the upper surface of the third resist 62 around the second opening 64. Therefore, the gate electrode 20 formed in the above-described manner can have the step portion 60 in the middle thereof in the vertical direction. Here, the portion of the gate electrode 20 higher than the step portion 60 has a larger width than the portion of the gate electrode 20 lower than the step portion 60. Alternatively, the Ti particles may be controlled so as to deposit up to the third resist 62 and further deposit in the upward direction with respect to the substrate on the upper surface of the third resist 62 around the second opening 64. After the deposition of the Ti particles is completed, the deposition of the Au particles may be performed.

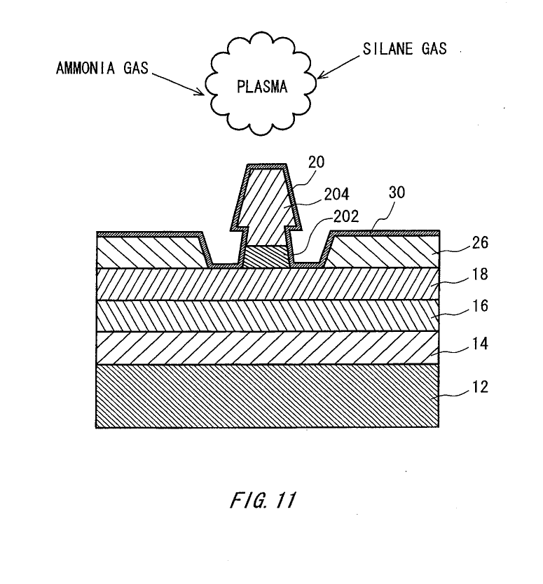

FIG. 11 illustrates the manufacturing process of the high electron mobility transistor 10 shown in FIG. 7, and shows the cross-sectional structure of the high electron mobility transistor 10 in which the SiN layer 30 has been formed. The first, second and third resists 42, 44 and 62 are removed. Subsequently, the SiN layer 30 is formed, on the externally exposed portion of the upper surface of the InGaP layer 18 (that is to say, a portion of the upper surface of the InGaP layer 18 in which neither the gate electrode 20 nor InGaP layer 18 is formed) and the upper and side surfaces of the gate electrode 20. Following this, a portion of the SiN layer 30 which is formed on the GaAs layer 26 is removed, to form the source/drain electrodes 28.

By performing the above-described steps, the high electron mobility transistor 10 shown in FIG. 7 can be manufactured. The high electron mobility transistor 10 manufactured in the above-described manner can produce similar effects to the high electron mobility transistor 10 shown in FIG. 1.

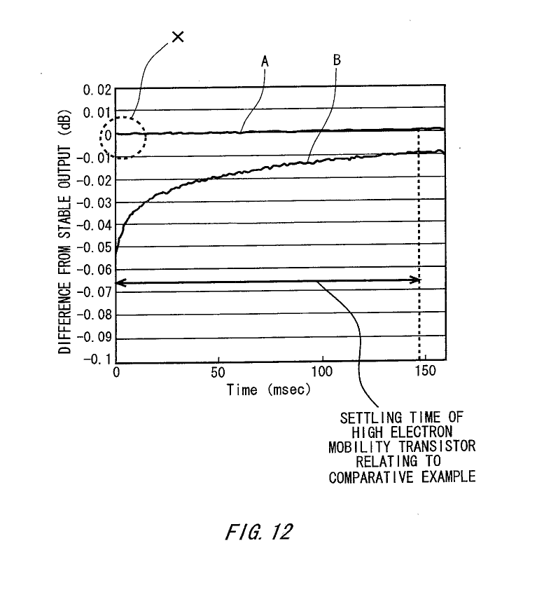

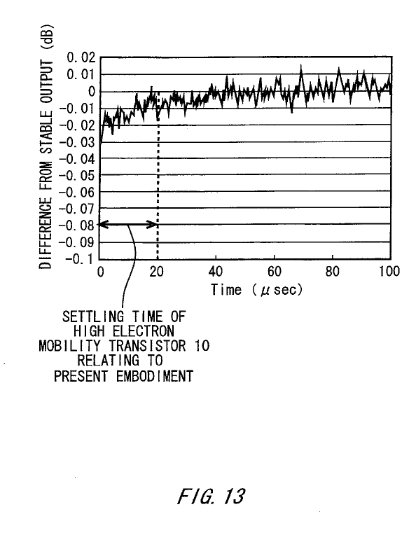

FIG. 12 illustrates the settling characteristics of the high electron mobility transistor 10 shown in FIG. 1 relating to the embodiment of the present invention and the settling characteristics of a high electron mobility transistor relating to a comparative example. FIG. 13 illustrates the characteristics shown in FIG. 12 in smaller units in terms of the horizontal axis (time axis). Note that a switching response is generally associated with a difference between the 10% level and the 90% level of a change in a voltage or current level. However, the settling characteristics shown in FIGS. 12 and 13 are associated with a difference between the 0% level and the 99.9% level of a rising or falling change.

The settling time shown in FIGS. 12 and 13 is measured under such a condition that a rising edge which varies from the L voltage (−2 V to −5 V) to the H voltage (0 V to 0.8 V) (or a falling edge which varies from the H voltage to the L voltage) is applied to the gate electrode and that the power input into the drain or source is output from the source or drain. To be more specific, the settling time shown in FIGS. 12 and 13 represents a time period from when the rising edge in the voltage is applied to when the output reaches the stable power range (the range defined as +−0.01 dB of the stable output power or the range defined as +−0.097% of the stable output voltage). Here, the signal input into the drain is a DC or RF signal (a signal having a frequency up to 100 GHz).

Here, the high electron mobility transistor relating to the comparative example is configured in such a manner that an AlGaAs buffer layer, an InGaAs channel layer, and an InGaP electron supply layer are sequentially deposited on a GaAs semiconductor substrate and that the gate electrode is made of platinum. Note that the high electron mobility transistor relating to the comparative example does not have a passivation layer made of SiN provided therein.

As shown in FIG. 12, the settling time of the high electron mobility transistor relating to the comparative example is approximately 140 milliseconds. On the other hand, the high electron mobility transistor 10 relating to the present embodiment achieves a settling time of approximately 20 microseconds as indicated in FIG. 13. In this way, the high electron mobility transistor 10 relating to the present embodiment can accomplish a very short settling time.

While an aspect of the present invention has been described through the embodiment, the technical scope of the invention is not limited to the above described embodiment. It is apparent to persons skilled in the art that various alternations and improvements can be added to the above-described embodiment. It is also apparent from the scope of the claims that the embodiments added with such alternations or improvements can be included in the technical scope of the invention.

What is claimed is:

1. A manufacturing method of a semiconductor apparatus, comprising:
forming an InGaP layer on a substrate; and
forming a gate electrode by vapor deposition on an upper surface of the InGaP layer, the gate electrode having a Ti layer and an Au layer.

2. The manufacturing method as set forth in claim 1, wherein
when the gate electrode having the Ti and Au layers is formed on the upper surface of the InGaP layer, the Ti and Au layers are formed with a substrate temperature being set equal to or lower than 180° C.

3. The manufacturing method as set forth in claim 1, wherein
a GaAs layer is further formed on the upper surface of the InGaP layer in a region different from a region in which the gate electrode is formed, and
a source electrode and a drain electrode are further formed on an upper surface of the GaAs layer.

4. The manufacturing method as set forth in claim 1, wherein
SiN having a refractive index in a range from no less than 1.5 to less than 1.9 is produced, and
after the gate electrode having the Ti and Au layers is formed on the upper surface of the InGaP layer, the SiN is deposited on the upper surface of the InGaP layer so as to form an insulating layer.

5. A semiconductor apparatus manufactured by:
forming an InGaP layer on a substrate; and
forming a gate electrode by vapor deposition on an upper surface of the InGaP layer, the gate electrode having a Ti layer and an Au layer.

6. A manufacturing method of a semiconductor apparatus, comprising:
forming an InGaP layer on a substrate;
forming an electrode on an upper surface of the InGaP layer;
producing SiN; and
depositing the SiN on the upper surface of the InGaP layer so as to form an insulating layer.

7. The manufacturing method as set forth in claim 6, wherein
the SiN has a refractive index in a range from no less than 1.5 to less than 1.9.

8. The manufacturing method as set forth in claim 6, wherein
the SiN is produced by using a plasma CVD method with a temperature being set so as to fall within a range from no less than 100° C. to no more than 200° C.

9. The manufacturing method as set forth in claim 7, wherein
the SiN is produced by using a plasma CVD method with a temperature being set at 150° C.

10. The manufacturing method as set forth in claim 9, wherein
the SiN is produced by the plasma CVD method with a use of an ammonia gas and a silane gas.

11. The manufacturing method as set forth in claim 10, wherein
the insulating layer has an oxygen composition ratio of higher than 0.5%.

12. The manufacturing method as set forth in claim 10, wherein
the insulating layer has a smaller linear thermal expansion coefficient than a film which has an SiN composition ratio of substantially 100%.

13. A semiconductor apparatus manufactured by:
forming an InGaP layer on a substrate;
forming an electrode on an upper surface of the InGaP layer;
producing SiN; and
depositing the SiN on the upper surface of the InGaP layer so as to form an insulating layer.

14. The semiconductor apparatus as set forth in claim 13, wherein
the SiN has a refractive index in a range from no less than 1.5 to less than 1.9.

15. The semiconductor apparatus as set forth in claim 13, wherein
the SiN is produced by using a plasma CVD method with a temperature being set so as to fall within a range from no less than 100° C. to no more than 200° C.

16. A manufacturing method of a semiconductor apparatus, comprising:
forming an InGaP layer on a substrate;
forming a GaAs layer on an upper surface of the InGaP layer;
removing a portion of the GaAs layer which corresponds to a gate formation region by using wet etching; and
forming a gate electrode on a portion of the upper surface of the InGaP layer which becomes exposed by the removal of the portion of the GaAs layer.
